(19) United States
(12) Patent Application Publication
(10) Pub. No.: US 2014/0175546 A1
(43) Pub. Date: Jun. 26, 2014

(54) PLASMONICALLY ENHANCED ELECTRO-OPTIC DEVICES AND METHODS OF PRODUCTION

(71) Applicant: The Regents of the University of California, Oakland, CA (US)

(72) Inventors: Diana Huffaker, Los Angeles, CA (US); Pradeep Senanayake, Los Angeles, CA (US); Chung Hong Hung, Los Angeles, CA (US)

(73) Assignee: The Regents of the University of California, Oakland, CA (US)

(21) Appl. No.: 14/073,670

(22) Filed: Nov. 6, 2013

Related U.S. Application Data
(60) Provisional application No. 61/723,110, filed on Nov. 6, 2012.

(51) Int. Cl. H01L 31/0232; H01L 27/144

(52) U.S. Cl. CPC H01L 31/02325; H01L 27/1446
USPC 257/342; 438/71

(57) ABSTRACT

A plasmonically enhanced electro-optic device includes a dielectric layer; a plurality of nanopillars arranged in a periodic array such that each nanopillar has a protruding portion that extends beyond a surface of the dielectric layer; a metallic layer formed on the surface of the dielectric layer and on portions of the plurality of nanopillars by an oblique directional deposition such that the metallic layer defines a periodic array of nano-holes and nano-antennas, each nano-hole of the periodic array of nano-holes being in a deposition shadow region of a corresponding nanopillar; and an electrode electrically connected to at least one nanopillar of the plurality of nanopillars at an end opposing the protruding portion thereof. Each nanopillar of the plurality of nanopillars includes a photo-absorption material, and the periodic array of nano-holes and nano-antennas have at least one of dimensions, uniformity or periodicity selected to enhance coupling of incident light into the plurality of nanopillars through excitation of surface plasmons.

### CROSS-REFERENCE TO RELATED APPLICATION

This application claims priority to U.S. Provisional Application No. 61/723,110 filed Nov. 6, 2012, the entire contents of which are hereby incorporated by reference.

This invention was made with Government support under Grant Nos. 0824273, 0903720, and 1007051, awarded by the National Science Foundation; and Grant No. N00244-09-1-0091, awarded by the Office of Naval Research. The Government has certain rights in this invention.

### BACKGROUND

1. Technical Field

The field of the currently claimed embodiments of this invention relates to electro-optic devices and methods of production, and more particularly to plasmonically enhanced electro-optic devices and methods of production.

2. Discussion of Related Art

Nanowires (NWs) and nanopillars (NPs) are pursued by many groups as an attractive route to device miniaturization and III-V/Si integration. The vertical orientation of these nanostructures facilitate both axial^{1,2} and coreshell^{3,4} p-n junctions which offer intriguing possibilities for device design and system architectures. For photodetectors and photovoltaics, the large surface to volume ratio allows efficient photon absorption and carrier extraction which enhances responsivity. To date, several photodetectors have been reported with promising characteristics such as single and NP arrays with photoconductive gain^{5,6}, and high-speed single NW devices^{7,8}. The majority of recent device demonstrations are based on self-assembled synthesis, which results in highly non-uniform NWs, which vary in placement, diameter and height. Thus, self-assembled NWs are often difficult to integrate into realistic device structures.

Device performance in a NW photodetector is often limited by the challenge of making good electrical contacts to the NWs using a material that is also sufficiently transparent to allow efficient electromagnetic coupling. Transparent conducting oxides like Indium Tin Oxide (ITO), and Aluminum Zinc Oxide (AZO) form Schottky barriers^{5,9} with GaAs, while ohmic metal contacts are not sufficiently transparent. Metal layers patterned with periodic nanohole (NH) arrays offer good electrical contacting while leveraging the phenomenon of extraordinary optical transmission for efficient absorption in the NP enabled by nanoplasmonic effects. The vertical geometry of a coreshell NW is particularly conducive to nanoplasmonic effects for electric-field enhancement and absorption since the depletion region is located very close to the surface. In contrast, surface plasmon (SP) enhancement in planar photodetectors is limited by the shallow penetration depth of the electric field intensity. To date surface plasmon enhanced photodetectors^{10,11} and solar cells¹² have been demonstrated with different metal grating configurations. Therefore, there remains a need for improved plasmonically enhanced electro-optic devices and methods of production.

### BACKGROUND REFERENCES

1 T. J. Kempa, B. Tian, D. R. Kim, J. Hu, X. Zheng, and C. M. Lieber, Nano Letters 8, 3456-3460 (2008).
2 A. Lysov, S. Vinaji, M. Offer, C. Gutsche, I. Regolin, W. Mertin, M. Geller, W. Prost, G. Bacher, and F.-J. Tegude, Nano Research, 1-9.
3 H. Goto, K. Nosaki, K. Tomioka, S. Hara, K. Hiruma, J. Motohisa, and T. Fukui, Applied Physics Express 2, 035004.
4 C. Colombo, M. Hei, M. Grätzel, and A. F. i. Morral, Gallium arsenide p-i-n radial structures for photovoltaic applications, Vol. 94 (AIP, 2009).
5 P. Senanayake, A. Lin, G. Mariani, J. Shapiro, C. Tu, A. C. Scofield, P. S. Wong, B. L. Liang, and D. L. Huffaker, Applied Physics Letters 97, 3.
6 C. Soci, A. Zhang, B. Xiang, S. A. Dayeh, D. P. R. Aplin, J. Park, X. Y. Bao, Y. H. Lo, and D. Wang, Nano Letters 7, 1003-1009 (2007).
7 L. Vj, J. Oh, A. P. Nayak, A. M. Katzenmeyer, K. Gilchrist, S. Grego, N. P. Kobayashi, S. Wang, A. A. Talin, N. K. Dhar, and M. M. Islam, Selected Topics in Quantum Electronics, IEEE Journal of PP, 1-31.
8 M. G. Eric, C. Guannan, C. Marc, M. Terrence, P. Paola, L. Nico, N. Bahram, and E. S. Jonathan, Picosecond response times in GaAs/AlGaAs core/shell nanowire-based photodetectors, Vol. 98 (AIP).
9 G. Mariani, P. S. Wong, A. M. Katzenmeyer, F. Leonard, J. Shapiro, and D. L. Huffaker, Nano Letters 11, 2490-2494.
10 C.-C. Chang, Y. D. Sharma, Y.-S. Kim, J. A. Bur, R. V. Shenoi, S. Krishna, D. Huang, and S.-Y. Lin, Nano Letters 10, 1704-1709.
11 F.-F. Ren, K.-W. Ang, J. Ye, M. Yu, G.-Q. Lo, and D.-L. Kwong, Nano Letters 11, 1289-1293.
12 J. N. Munday and H. A. Atwater, Nano Letters 11, 2195-2201.

### SUMMARY

A plasmonically enhanced electro-optic device according to an embodiment of the current invention includes a dielectric layer; a plurality of nanopillars arranged in a periodic array such that each nanopillar has a protruding portion that extends beyond a surface of the dielectric layer; a metallic layer formed on the surface of the dielectric layer and on portions of the plurality of nanopillars by an oblique directional deposition such that the metallic layer defines a periodic array of nano-holes and nano-antennas, each nano-hole of the periodic array of nano-holes being in a deposition shadow region of a corresponding nanopillar; and an electrode electrically connected to at least one nanopillar of the plurality of nanopillars at an end opposing the protruding portion thereof. Each nanopillar of the plurality of nanopillars includes a photo-absorption material, and the periodic array of nano-holes and nano-antennas have at least one of dimensions, uniformity or periodicity selected to enhance coupling of incident light into the plurality of nanopillars through excitation of surface plasmons.

A method of producing an electro-optic device according to an embodiment of the current invention includes providing a semiconductor substrate; forming a mask layer on the semiconductor substrate, the mask layer defining a plurality of nano-holes therethrough to expose a pattern of regions of the semiconductor substrate; growing a plurality of nanopillars from the plurality of nano-holes to provide a periodic array of nanopillars; depositing a dielectric layer over the semiconductor substrate such that each nanopillar of the plurality of nanopillars has a protruding portion that extends beyond a surface of the dielectric layer; and directionally depositing a metallic layer over the surface of the dielectric layer and portions of protruding portions of the plurality of nanopillars such that the metallic layer defines a periodic array of nano-holes in deposition shadow regions of the plurality of nanopillars and a plurality of nano-antennas on the plurality of nanopillars.

### BRIEF DESCRIPTION OF THE DRAWINGS

Further objectives and advantages will become apparent from a consideration of the description, drawings, and examples.

FIG. 1A is an example of In_{0.4}Ga_{0.6}As NPs grown on n+ GaAs by selective area MOCVD arranged in a square lattice with a 1 μm pitch prepared for an embodiment of the current invention.

FIG. 1B is a tilted SEM at 52° of the gold coated NPs corresponding to the example of FIG. 1A.

FIG. 1C is a schematic illustration of a NP photodetector array according to an embodiment of the current invention.

FIGS. 2A and 2B show a) Dark and light I-V characteristics of gold NH device according to an embodiment of the current invention, and b) Photoresponse of NP/NH photodetector showing SP_{(±1,±1)} modes, and control device with ITO top contact.

FIGS. 3A, 3B, and 3C show a) High resolution SEM of the NP in the NH, and orientation of light polarization of an embodiment of the current invention; b) corresponding photoresponse for x- and y-polarized light; and c) corresponding polarization dependent photocurrent at 1100 nm showing cos²(φ) angular dependence

FIG. 4A is a schematic illustration of a photodetector according to an embodiment of the current invention showing orientation in the angle dependent photoresponse measurement.

FIG. 4B shows angular photoresponse of the gold NH array photodetector corresponding to FIG. 4A showing the shift and splitting of the SP_{(±1,±1)} resonances.

FIGS. 5A, 5B, 5C, 5D, and 5E show spatial profile of the power absorbed in the structure a) for the x-polarization in the b) x-y plane and c) x-z plane. Spatial profile of the power absorbed in the structure for the y-polarization in the d) x-y plane and e) x-z plane. Scale bar is 200 nm.

FIG. 6A is a schematic illustration of a) a Nanopillar Optical Antenna (NOA) according to an embodiment of the current invention.

FIGS. 6B-6C show contour plot of the Qabs as b) w is varied, and c) as h is varied.

FIG. 7A-7B show a) Absorption enhancement due to the Localized Surface Plasmon (LSPR) supported by the metal cap for the embodiment of FIG. 6A; and b) Electric field intensity profile of LSPR mode at 1270 nm in x-z plane.

FIGS. 8A, 8B, and 8C show a) Electric field intensity in the y-z plane of the LSPR mode at 1270 nm and the corresponding electric field in b) the z-direction E_{z} and c) y-direction E_{y}.

FIGS. 9A, 9B, and 9C show a) The full-wave simulation of the optical absorption in the nanopillar array for P=580 nm. Power absorbed in the x-z plane for b) the SPP mode and c) LSPR mode.

FIGS. 10A-10B show a) Measured angular photoresponse spectra of PENPD showing enhanced photocurrent due to both SPP_{-1,0} and LSPR modes. P=580 nm w=160 nm h=320 nm b) Fitting of the SPP-BW and LSPR before and after overlap at 0° and 30°.

FIGS. 11A-11B show a) Simulated photonic bandstructure of NP-PEPD with P=580 nm showing the SPP-BW Gold-BCB modes and Gold-Air modes; and b) the absorbed power in the nanopillar.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

The term “nanopillar” is intended to have a broad meaning to include structures that have at least cross sectional dimensions that are less than 1 μm. In some cases, the longest, or longitudinal, dimension of the nanopillar can be greater than 1 μm, but the other two mutually orthogonal cross sectional dimensions will be less than 1 μm. However, in some cases all dimensions can be less than 1 μm. In some cases, the terms nanopillar, nanorod and nanowire can be used interchangeably. In addition, the term nanopillar does not imply a certain cross-sectional shape, which can vary along the length of the nanopillar in some cases, or from nanopillar to nanopillar.

The term “light” is intended to have a broad meaning to include both visible and non-visible regions of the electromagnetic spectrum. For example, infrared and ultraviolet light are intended to be included within the broad definition of the term “light”.

An embodiment of the current invention can provide a periodic arrangement of the metal holes, and the optoelectronic functionality enabled by the periodic three-dimensional metal hole array (3DMHA). This technique can be applied to any nanostructure to make a periodic metal hole array. It is found that the polarization sensitivity of nanowire arrays can be controlled by the orientation of the polarization with respect to the metal hole. Since the metal deposited around the nanostructure is optically opaque, light is focused into subwavelength apertures resulting in enhanced electric field intensities. In addition, broad band absorption (400 nm-1200 nm) has been observed from 3DMHA on nanopillars according to some embodiments of the current invention. The 3DMHA is self-aligned to the nanostructure, not lithographically defined.

The fabrication process for 3DMHA on nanowire arrays according to some embodiments of the current invention can be generalized to any regularly arranged array of nanostructures. First, the nanowires or nanostructures can be partially planarized (using spin-on glass or polymer resin) to control the size of the nano-hole. The planarization layer can be etched back to expose the nanopillar/nanostructure tips. The etch-back can be done either by dry etching (reactive-ion) or wet etching. Second, metal is evaporated on the nanowire array or nanostructures at a tilted angle. The thickness of the metal in the planar region can be thick enough to be opaque (˜200 nm of gold is opaque in the visible). The pitch of the metal hole array is determined by the pitch of the nanowires, the width of the nano-holes is determined by the diameter of the nanowires. The length of the nano-hole is determined by the height of exposed pillar tip, and angle of tilted deposition. Thus, different metal nano-hole geometries can be engineered, following the symmetry of the nanostructure array or not. The metal can be either an ohmic or Schottky contact on top of the nanopillars. The resulting shadow from the tilted deposition produces the nano-hole. The tilted metal evaporation will define the top contact of the device, while more contacts (bottom contacts) can be evaporated depending on the device geometry. The nanowires/nanopillars or nanostructures need to be periodic for the 3DMHA to be periodic. The periodicity of the metal holes, the self-aligned nature of the contact, and the subwavelength (for visible and near IR) nano-holes is a novel aspect of a fabrication process according to some embodiments of the current invention.

Some embodiments of the current invention can include a plasmonically enhanced solar cell, photodetector or light emitter. Applications in photovoltaics is possible because broad band absorption is observed. However, if the pitch can be optimized to utilize plasmon resonances of the metal hole array, then enhanced photoabsorption can be utilized at a certain resonance wavelength. The self-aligned 3DMHA can also be designed as a broadband focusing lens enabling ultra-small photodetectors.

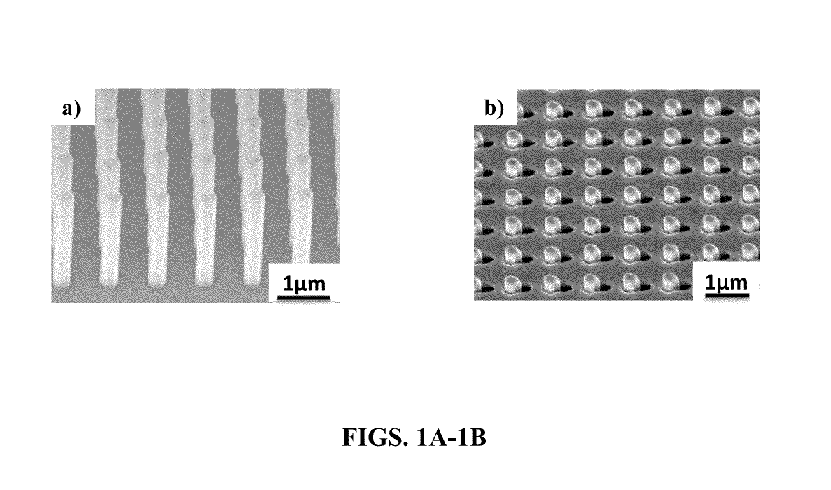

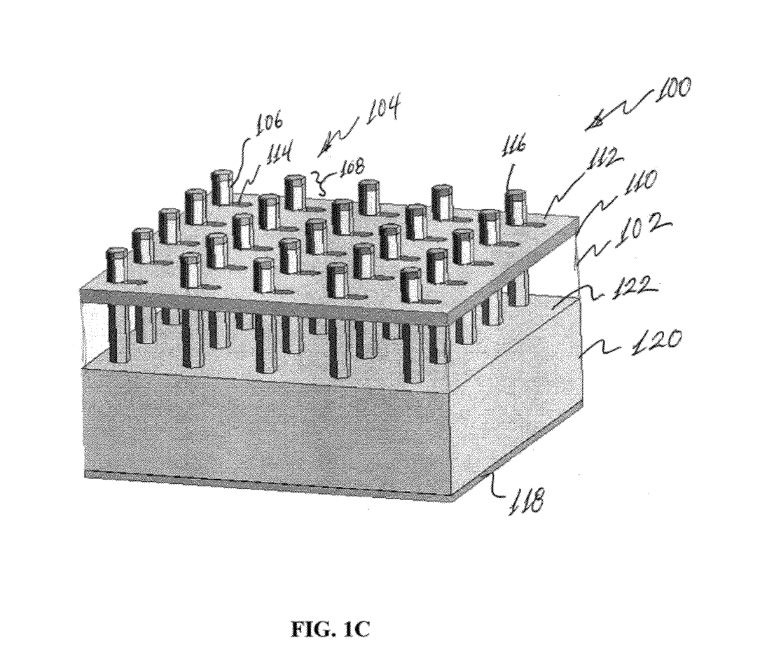

FIGS. 1A-1C show an example of a plasmonically enhanced electro-optic device 100 according to an embodiment of the current invention. In FIG. 1C, the plasmonically enhanced electro-optic device 100 includes a dielectric layer 102, a plurality of nanopillars 104 arranged in a periodic array such that each nanopillar (for example, nanopillar 106) has a protruding portion 108 that extends beyond a surface 110 of the dielectric layer 102. The plasmonically enhanced electro-optic device 100 also includes a metallic layer 112 formed on the surface 110 of the dielectric layer 102 and on portions of the plurality of nanopillars 104 by an oblique directional deposition such that the metallic layer 112 defines a periodic array of nano-holes (e.g., nano-hole 114) and nano-antennas (e.g., nano-hole 116). Each nano-hole of the periodic array of nano-holes is in a deposition shadow region of a corresponding nanopillar. The plasmonically enhanced electro-optic device 100 also includes an electrode 118 electrically connected to at least one nanopillar of the plurality of nanopillars at an end opposing the protruding portion thereof. Each nanopillar of the plurality of nanopillars 104 includes a photo-absorption material. The periodic array of nano-holes and nano-antennas have at least one of dimensions, uniformity or periodicity selected to enhance coupling of incident light into the plurality of nanopillars 104 through excitation of surface plasmons.

The plurality of nanopillars 104 can be grown on portions of a semiconductor substrate 120, for example. The semiconductor substrate 120 can have a mask layer 122 that defines an array of nano-holes therethrough in order to grow the plurality of nanopillars 104 from exposed surface regions of said semiconductor substrate 120. In some embodiments, the dielectric layer 102 can be formed on the mask layer 122, over the semiconductor substrate 120. The electrode 118 can be formed on a surface of the semiconductor substrate 120 to be electrically connected to all of the plurality of nanopillars 104 in some embodiments of the current invention.

In some embodiments, the periodic array of nano-holes can have substantially uniform hole sizes and shapes arranged with a periodicity to provide enhanced coupling through Surface Plasmon Polariton Block Waves.

In some embodiments, the nano-antennas can have a height above the surface 110 of the dielectric layer 102 and a width selected to provide enhanced coupling through Localized Surface Plasmon Resonances.

In some embodiments, the nano-antennas have a height of at least 150 nm and less than 800 nm above said surface 110 of said dielectric layer 102. In some embodiments, the nano-antennas can have a width of at least the wavelength divided by three times refractive index of the material and less than the wavelength to be detected. In some embodiments, the metallic layer can include at least one of gold, silver, chromium, copper or any drude material.

A method of producing an electro-optic device according to an embodiment of the current invention includes providing a semiconductor substrate; forming a mask layer on the semiconductor substrate, the mask layer defining a plurality of nano-holes therethrough to expose a pattern of regions of the semiconductor substrate; growing a plurality of nanopillars from the plurality of nano-holes to provide a periodic array of nanopillars; depositing a dielectric layer over the semiconductor substrate such that each nanopillar of the plurality of nanopillars has a protruding portion that extends beyond a surface of the dielectric layer; and directionally depositing a metallic layer over the surface of the dielectric layer and portions of protruding portions of the plurality of nanopillars such that the metallic layer defines a periodic array of nano-holes in deposition shadow regions of the plurality of nanopillars and a plurality of nano-antennas on the plurality of nanopillars.

In some embodiments, the method can further include selecting an angle of the directionally depositing step relative to the surface of the dielectric layer such that nano-holes of the periodic array of nano-holes have preselected lengths extending from a respective nanopillar.

In some embodiments, the method can further include selecting a dimension of the plurality of nano-holes through the mask layer such that the plurality of nano-holes of the metallic layer and the plurality of nano-antennas have a preselected width.

In some embodiments, the step of growing the plurality of nanopillars grows the plurality of nanopillars to a preselected height, and the step of depositing the dielectric layer over the semiconductor substrate is deposits it to a preselected thickness such that the plurality of nano-antennas have a preselected height and the array of nano-holes have preselected lengths extending from respective nanopillars.

### EXAMPLES

The following examples help explain some concepts of the current invention. However, the general concepts of the current invention are not limited to the particular examples.

### Example 1

In the following example, we demonstrate a metal NH array self-aligned to patterned NPs to realize surface plasmon-enhanced photodiodes. The self-aligned NHs are fabricated by evaporating the top contact metallization at an off-normal angle, so that the NW tip itself acts as a shadow mask. This eliminates the need for process-intensive lithography to separately define the subwavelength gold NHs. The periodicity of the metal NH array supports surface plasmon polaritons Bloch waves (SPP-BW) resonances, which cannot be realized by randomly oriented NPs.

FIG. 1A shows an example of a NP array before processing, and FIG. 1B shows an SEM image of the fully processed photodiode arrays. A schematic of the final device is shown in FIG. 1C. For the devices studied here, p-doped In_{0.4}Ga_{0.6}As NPs are grown by selective-area epitaxy (SAE) on n+ doped GaAs (111) B substrates. The NPs have a height of 1.5 μm, a diameter of 200 nm, and are arranged in a 1 μm pitch square lattice. The NP doping concentration is estimated to be 5×10¹⁷ cm⁻³ from single pillar resistivity measurements. A more detailed description of substrate patterning and NP epitaxy are published elsewhere¹³.

Following epitaxy, the NP array is planarized using Benzocyclobutene (BCB), which is hard-cured and etched back to expose ˜500 nm of the NP tips. The top metal contact (Cr: 20 nm, Au: 200 nm) is deposited at 35° from the substrate normal to form an inherent device asymmetry. The angled beam coats both top and the exposed side of each NP along with the entire surface interconnecting the pillars. The NP “shadow” leaves the other pillar side uncoated and forms a self-aligned NH adjacent to each NP. The NH length depends on the exposed tip length and the incident angle of metal deposition, while the NH width is defined by the NP diameter. In this example, the resulting NHs are 260 nm wide and 315 nm long. This metal NH array forms a 2D plasmonic crystal self aligned to the NPs. Each NP/NH photodiode array area is 500 μm×500 μm in area with a pitch of 1 μm. For comparison, an otherwise identical device was also fabricated with a uniform ITO top contact instead of the Cr/Au NH array. Since ITO is not a plasmonic material in the wavelength range of interest, this serves as a control device to isolate the effect of the metal NH array. After fabrication, the NP photodetectors are wire bonded to a leadless chip carrier for electrical and optical characterization.

Propagating electromagnetic energy can be coupled into the NP through the NHs in the gold contact via SP modes supported by the metal NH-NP geometry. A first order approximation of the resonant transmission wavelengths of the NH array is described by Eqn (1),

$${λ}_{m} = \frac{P}{\sqrt{{i}^{2} + {j}^{2}}} Re ( \sqrt{\frac{{ɛ}_{m} {ɛ}_{d}}{{ɛ}_{m} + {ɛ}_{d}}} ) \qquad ( 1 )$$

where P is the pitch of the hole array, ∈ₘ is the dielectric constant of the metal, ∈_{d} is the dielectric constant of the dielectric medium, and (i, j) are the scattering orders of the hole array in the x- and y-directions^{14,15}.

This equation describes the conservation of momentum condition necessary to couple to propagating SPP-BW modes. Equation 1 can be can be instructive in identifying different orders of the surface plasmon modes excited by the metal NH array. For the device studied here, the 2D plasmonic crystal pitch, P=1 μm, yields the SP_{(0,±1)} and SP_{(±1,±1)} resonances at λ=1616 nm and λ=1142 nm respectively. ∈_{d} is assumed to be 2.56, for the BCB polymer material used to planarize the NP array. The dielectric constant of gold, ∈ₘ (λ) is interpolated from experimental values published by Johnson and Christy¹⁶.

The phenomenon of extraordinary optical transmission involves propagating SPP-BW modes coupling to modes of the individual NH, which could either be waveguide modes or localized surface plasmon (LSP) modes. These NH modes in turn excite similar modes on the other side of the metal film which interfere and create a propagating wave in the far-field. In our geometry, we want to exploit the localized “hot spots” of enhanced electric field in the vicinity of the NHs, in such a way to enhance absorption within the NPs. The electric field hot spots formed by the NH grating, described by Eqn. 1, will enhance photodetection given appropriate spatial and spectral overlap with NP absorption region.^{17,18} We note the first order SP resonance SP_{(0,±1)} is longer (λ=1616 nm) than the cut-off wavelength of the In_{0.4}Ga_{0.6}As NPs at λ=1475 nm. However, enhanced photoresponse can be observed due to the SP_{(±1,±1)} mode at λ=1142 nm.

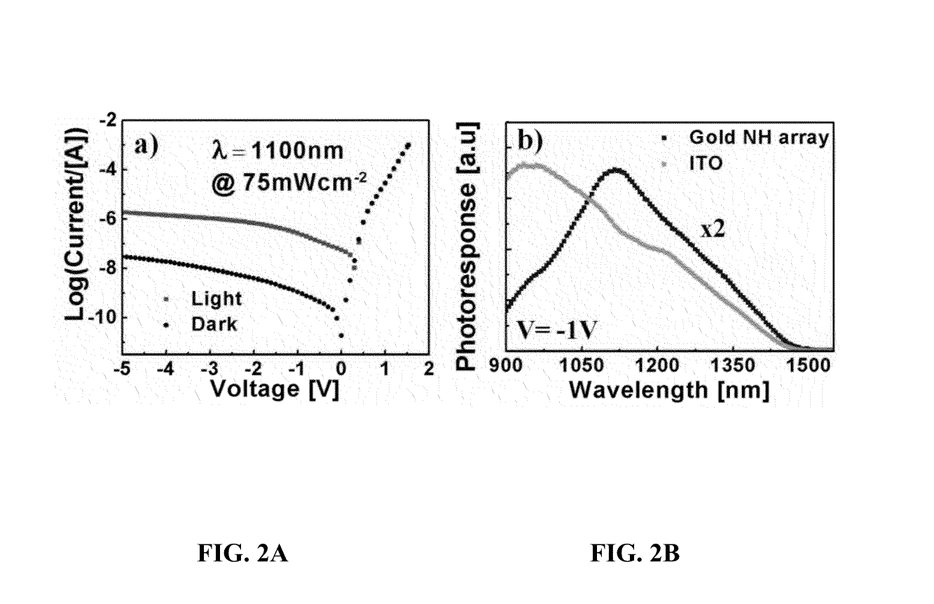

The NP photodiode current-voltage (I-V) characteristic is measured under dark and light conditions with a semiconductor parameter analyzer. The I-V characteristic is typical of a photovoltaic detector as shown in FIG. 2A. The depletion region of the photodiode is located at the NP-substrate interface. The ideality factor of the diode is 1.9, while the rectification ratio at +/−1 V is >10⁴. Under dark conditions, the reverse leakage current of 30 nA at −5 V indicates high quality material including low threading dislocations density that could have been formed at the InGaAs NP-substrate interface. Under illumination (λ=1100 nm at 75 m Wcm⁻²), a responsivity of 0.28 A/W is measured at −5 V. The spectral response of the device is measured using light from a quartz tungsten halogen lamp dispersed by a grating monochromator followed by a depolarizer. The depolarizer is necessary to remove the polarization dependence of the monochromator grating. Photocurrent from the devices is measured using a lock-in amplification technique. FIG. 2B shows the spectral response of the gold NH device and the ITO control device, where both devices are reverse biased at −1 V. The ITO control device shows peak responsivity at λ=980 nm and a cut-off wavelength of λ=1470 nm. In contrast, the NP/NH array device has peak responsivity at λ=1112 nm with the same the same cut-off wavelength. The peak responsivity around λ=1112 nm is attributed to the resonant coupling of the SP_{(±1,±1)} modes into the NP resulting is higher photoabsorption. The ITO control device has twice the responsivity of the NP/NH device. The lower responsivity of the NP/NH array device is attributed to the small spatial overlap between the NP-substrate depletion region and the NH-generated e-field “hot-spots”. This overlap can be optimized in future designs using a coreshell geometry.

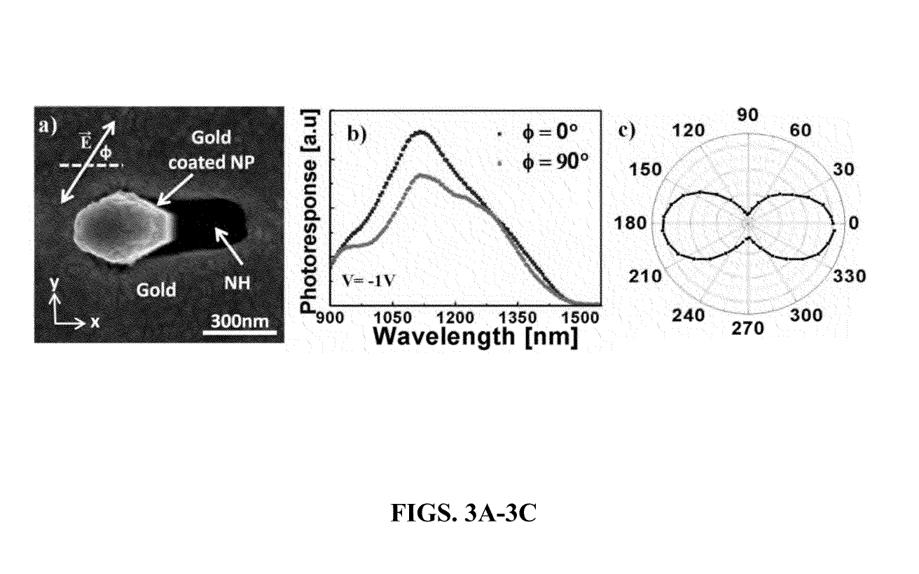

Effects of NH/NP asymmetry are elucidated through polarization-specific spectral response of the device described in FIGS. 3A-3C. The polarization of light with respect to the NH is shown in FIG. 3A, where light polarized parallel to the NH is x-polarized, and perpendicular to the NH is y-polarized. Polarization orientation is delineated using angle φ. FIG. 3B shows the photoresponse of the NH/NP device when incident light is polarized parallel and perpendicular to the NH where φ=0° and 90°, respectively. The x-polarized light (φ=0°) produces a higher photocurrent compared to the y-polarized light (φ=90°) for much of the photoresponse spectrum. The photocurrent is measured at the peak responsivity of λ=1100 nm from φ=0° through a full 360° revolution at 10° increments. FIG. 3C shows a polar plot of the photocurrent for incident wavelength at 1100 nm. The maximum photocurrent is measured for the x-polarization with a 25% drop in the photocurrent y-polarized light. The photocurrent shows a cos² φ dependence on the incident light polarization similar to the optical antenna behavior observed with gold nanorods¹⁹. This dipole-like dependence is attributed to the specific nature of the Localized Surface Plasmon (LSP) that is excited in the gold NH which couples light into the NP^{20,21}. In the case of the ITO control device there is no dependence of the photoresponse on polarization.

While polarization specific photoresponse shows that localized surface plasmons produce enhanced electric fields in the NP, it does not provide information about the SPP-BW resonances of the 2D plasmonic crystal. Thus, angular photoresponse measurements are performed to investigate the effect of incident angle on the BW resonances^{10,22,23}. Angular photoresponse measurements allow the in plane momentum of the incident light to be varied as kₒ sin(θ), where θ is the angle from the sample normal by tilting the sample relative to incident beam. Since surface plasmons have greater momentum than freely propagating light, coupling to a SP mode requires momentum from the 2D plasmonic lattice. For a square lattice, this lattice momentum is given by (2π/P). As the in-plane momentum of the incident light is varied the condition for momentum matching to SPP-BWs is changed. The SPP-BW resonances described by Equation (1) are no longer satisfied. It can be shown that for a 2D plasmonic crystal with in-plane momentum in only the y-direction the Bragg coupling condition is given by²²

$${k}_{o} Re ( \sqrt{\frac{{ɛ}_{m} {ɛ}_{d}}{{ɛ}_{m} + {ɛ}_{d}}} ) = \vert ( {k}_{0} sin ( θ ) \pm j \frac{2 π}{P} ) \hat{y} \pm i \frac{2 π}{P} \hat{x} \vert \qquad ( 2 )$$

From Equation (2) it can be seen that the SP_{(±1,±1)} degenerate modes will split into the SP_{(±1,-1)} and SP_{(±1,1)} modes with increasing incident angle (θ). Qualitatively, as θ is increased the SP_{(±1,-1)} modes will red-shift and the SP_{(±1,1)} modes will blue shift to satisfy momentum matching.

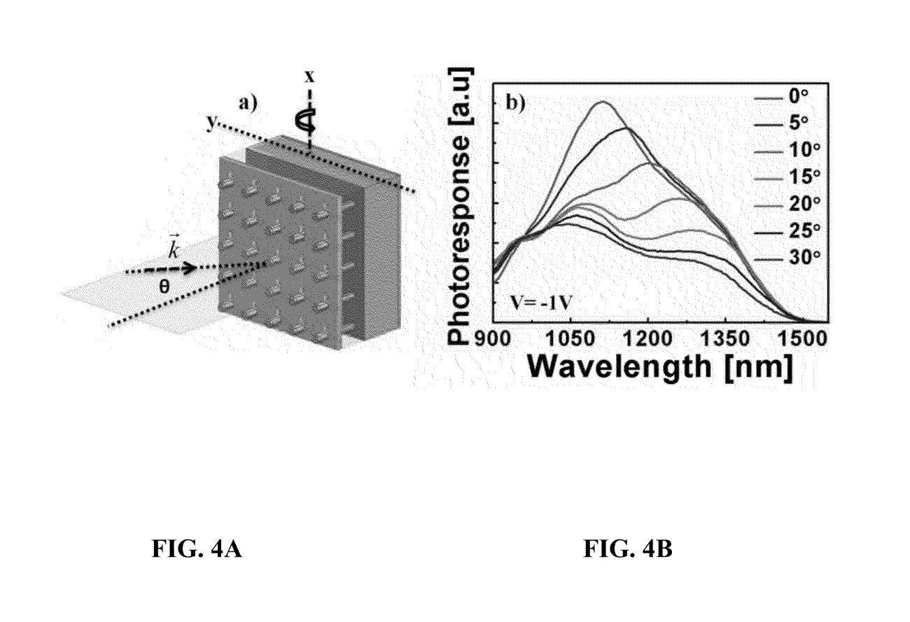

FIGS. 4A and 4B show the schematic of the sample orientation for the angular photoresponse measurement and the angular photoresponse spectra. Light is polarized along the long length of the nanohole such that θ=0. The gold NH detector is placed on a 360° rotation mount with a minimum resolution of 2°, and rotated about the x-axis. At normal incidence (θ=0) the SP_{(±1,±1)} modes are degenerate, which results in the peak at 1112 nm. As θ is increased from 0-10° the peak photoresponse at 1112 nm red shifts due to the SP_{(±1,-1)} modes, and also broadened due to the SP_{(±1,1)} modes. At 15° it is clearly observed that the photoresponse spectrum has split into two peaks. These two clearly distinguishable peaks are due to the SP_{(±1,1)} modes at 1080 nm and SP_{(±1,-1)} modes at 1270 nm. As the θ is increased beyond 15° the SP_{(±1,1)} modes blue shift further such that the peak responsivity is 1045 nm at θ=30°. Angular photoresponse measurements thus confirm that SPP-BW can be excited on the gold NH array such that it acts as a 2D plasmonic crystal.

To further understand the physics of the electric field intensity enhancements in the NP a full wave 3D model was constructed of the hexagonal NP with a gold NH array contact using the commercial software Lumerical. The electric field intensity was numerically computed inside the NP using the finite difference time domain (FDTD) technique. The incident light source is polarized in both x- and y-polarizations with a plane wave source excitation at 1100 nm. A 3D unit cell is defined such that periodic boundary conditions with a 1 μm pitch are used in the x-y boundaries, while a perfectly matched layer boundary condition is used in the z-boundaries. GaAs material parameters are used to define the hexagonal NP and the substrate. The polymer planarization layer BCB is modeled as silicondioxide, and gold is modeled by the material parameters described by Johnson et al¹⁶.

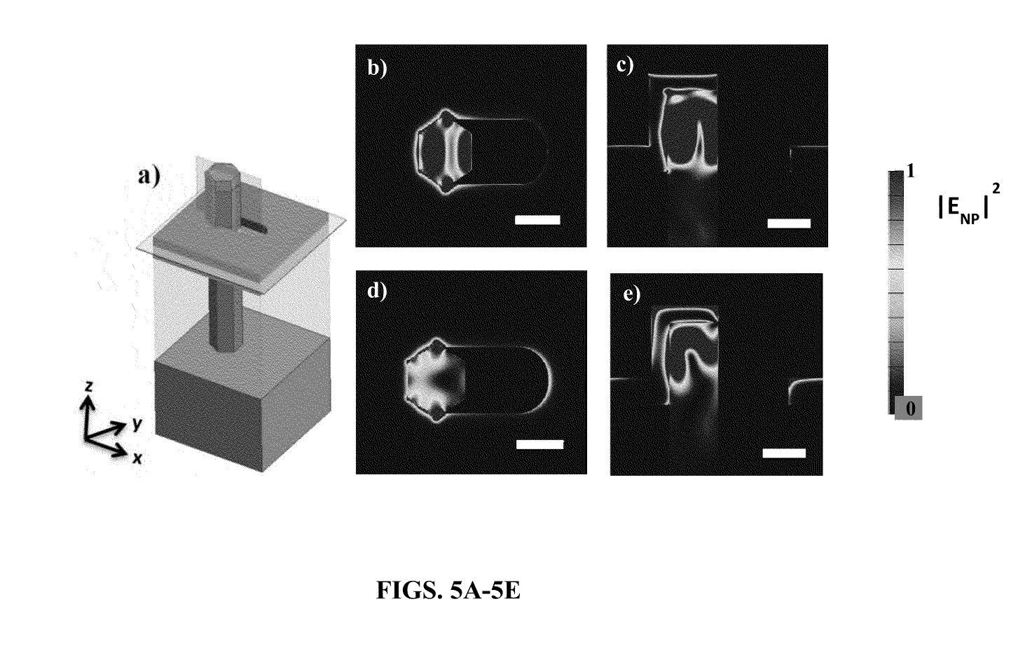

FIG. 5A shows an illustration of the 3D structure modeled by FDTD and the locations in the structure where the electric field intensity is visualized. The electric field intensity is extracted in the x-y plane through the NP and the metal NH, and also x-z plane through the center of the NP. FIG. 5B shows the electric field intensity in the hexagonal NP and NH when the incident electric field intensity is x- and y-polarized at 1100 nm. Within the borders of the hexagonal NP outlined in white there are significant electric field intensity enhancements. The electric field intensity enhancement is greater for x-polarized light compared to y-polarized light in the bulk of the NP. In addition, for x-polarized light there are more intense electric field intensity hot spots in the NP, these enhanced electric field intensity results in higher photogeneration in the NP, which explains the experimentally measured higher photoresponse for x-polarized light. FIG. 5C shows the electric field intensity in the x-z plane at the center of the NP. The electric field intensity enhancements decay rapidly below the exposed NP tip characteristic of a surface plasmon field profile. The greatest field enhancement occurs directly under the metal contact 30 nm below the top surface of the NP. The electric field intensity does not penetrate to the depletion region at the NP-substrate interface explaining the experimentally measured low absolute responsivity.

In summary, we have demonstrated a novel type of photodetector based on surface plasmon field enhancements in NP arrays according to an embodiment of the current invention. The metal NH array acts as a 2D plasmonic crystal such that both SPP-BWs and LSPs couple light into the NP. The periodicity, metal NH shape, and metal dielectric function can be engineered to absorb light in different spectral ranges. The grating periodicity sets the peak responsivity via SPP-BWs while the NW asymmetry produces polarization-dependent photoresponse via LSPs. FDTD modeling confirms the existence of electric field intensity hot spots in the nanopillar. Plasmonic NP photodetectors can offer significant advantages over planar devices in terms of reduced leakage current and smaller capacitance. Plasmonic NP array devices can have applications in plasmonically enhanced focal plane arrays, and nanostructure photovoltaic devices.

### EXAMPLE 1 REFERENCES

1 T. J. Kempa, B. Tian, D. R. Kim, J. Hu, X. Zheng, and C. M. Lieber, Nano Letters 8, 3456-3460 (2008).
2 A. Lysov, S. Vinaji, M. Offer, C. Gutsche, I. Regolin, W. Mertin, M. Geller, W. Prost, G. Bacher, and F.-J. Tegude, Nano Research, 1-9.
3 H. Goto, K. Nosaki, K. Tomioka, S. Hara, K. Hiruma, J. Motohisa, and T. Fukui, Applied Physics Express 2, 035004.
4 C. Colombo, M. Hei, M. Grätzel, and A. F. i. Morral, Gallium arsenide p-i-n radial structures for photovoltaic applications, Vol. 94 (AIP, 2009).
5 P. Senanayake, A. Lin, G. Mariani, J. Shapiro, C. Tu, A. C. Scofield, P. S. Wong, B. L. Liang, and D. L. Huffaker, Applied Physics Letters 97, 3.
6 C. Soci, A. Zhang, B. Xiang, S. A. Dayeh, D. P. R. Aplin, J. Park, X. Y. Bao, Y. H. Lo, and D. Wang, Nano Letters 7, 1003-1009 (2007).
7 L. Vj, J. Oh, A. P. Nayak, A. M. Katzenmeyer, K. Gilchrist, S. Grego, N. P. Kobayashi, S. Wang, A. A. Talin, N. K. Dhar, and M. M. Islam, Selected Topics in Quantum Electronics, IEEE Journal of PP, 1-31.
8 M. G. Eric, C. Guannan, C. Marc, M. Terrence, P. Paola, L. Nico, N. Bahram, and E. S. Jonathan, Picosecond response times in GaAs/AlGaAs core/shell nanowire-based photodetectors, Vol. 98 (AIP).
9 G. Mariani, P. S. Wong, A. M. Katzenmeyer, F. Leonard, J. Shapiro, and D. L. Huffaker, Nano Letters 11, 2490-2494.
10 C.-C. Chang, Y. D. Sharma, Y.-S. Kim, J. A. Bur, R. V. Shenoi, S. Krishna, D. Huang, and S.-Y. Lin, Nano Letters 10, 1704-1709.
11 F.-F. Ren, K.-W. Ang, J. Ye, M. Yu, G.-Q. Lo, and D.-L. Kwong, Nano Letters 11, 1289-1293.
12 J. N. Munday and H. A. Atwater, Nano Letters 11, 2195-2201.
13 J. N. Shapiro, A. Lin, P. S. Wong, A. C. Scofield, C. Tu, P. N. Senanayake, G. Mariani, B. L. Liang, and D. L. Huffaker, Applied Physics Letters 97, 243102-243102-3 (2010).
14 C.-Y. Chang, H.-Y. Chang, C.-Y. Chen, M.-W. Tsai, Y.-T. Chang, S.-C. Lee, and S.-F. Tang, Applied Physics Letters 91, 163107-3 (2007).
15 S.-H. Chang, S. Gray, and G. Schatz, Opt. Express 13, 3150-3165 (2005).
16 P. B. Johnson and R. W. Christy, Physical Review B 6, 4370 (1972).
17 R. Carsten, F. Stephan, and L. Falk; Vol. 104 (AIP, 2008), p. 123102.
18 W. L. Barnes, A. Dereux, and T. W. Ebbesen, Nature 424, 824-830 (2003).
19 M. W. Knight, H. Sobhani, P. Nordlander, and N. J. Halas, Science 332, 702-704.
20 K. J. K. Koerkamp, S. Enoch, F. B. Segerink, N. F. van Hulst, and L. Kuipers, Physical Review Letters 92, 4 (2004).
21 A. Degiron and T. W. Ebbesen, Journal of Optics a-Pure and Applied Optics 7, S90-S96 (2005).
22 H. Gao, W. Zhou, and T. W. Odom, Advanced Functional Materials 20, 529-539.
23 S. Williams and J. Coe, Plasmonics 1, 87-93 (2006).

### Example 2

Bottom up nanopillars are promising candidates as absorbers for photodetector applications. Their small volume and high material quality results in a lower leakage current and junction capacitance leading to better noise performance and high-speed operation compared to typical planar photodetectors [1, 2]. However, there is typically a tradeoff between the size of the absorbing volume and the quantum efficiency of the photodetector when the thickness of the semiconductor junction is reduced below the optical absorption length [3]. A potential solution to this trade-off is to take advantage of surface plasmon antenna structures to concentrate light below the diffraction limit [4]. In this way, the optical collection area can be decoupled from the volume of the absorbing material enabling a small volume photodetector to have high absorption efficiency.

Surface plasmons in the form of Surface Plasmon Polariton Bloch Waves (SPP-BW) and Localized Surface Plasmon Resonances (LSPR) can be used to funnel light into the subwavelength absorption volume. Typically, the nanopillar absorption cross-section is restricted to the cross-section of the nanopillar. However, by utilizing SPP-BW and LSPRs light can be funneled into the nanopillar supported by plasmonic resonances of the self-aligned metal hole lattice and partial metal shell on the nanopillar, thus increasing the absorption cross section of the pillar. To date there have been several reports demonstrating surface plasmon enhanced photodetectors using dipole antennas, metal hole arrays, and bullseye gratings [5-8]. It has also been shown that coupling of incident light with evanescent field of a plasmonic Fabry Perot resonance can lead to extraordinary optical absorption [9]. Schottky photodetectors on silicon have also been demonstrated where the absorption of surface plasmons in the metal results in hot electrons being excited over the Schottky barrier resulting in a photocurrent. However, the efficiency of these detectors have been limited by ohmic losses in the metal [10]. The most essential requirement for enhancing the efficiency of plasmonic photodetectors is the electric field intensity being enhanced in the semiconductor nanopillar rather than the lossy metal [4, 11]. We have demonstrated nanopillar based plasmonically-enhanced photodetectors (NP-PEPDs) where this condition is met by using a metal surface with nanoscale apertures self-aligned to the nanopillar photodetectors. The photoresponse of the NP-PEPDs resulted from the enhanced SPP-BW absorption due to the periodicity of the metal holes self-aligned to the nanopillar array [11]. In this example, NP-PEPDs have been designed to utilize both SPP-BWs and LSPRs due to the Nanopillar Optical Antenna (NOA) in the photoresponse spectrum, such that the hybridization of the SPP-BWs and LSPRs results in enhanced photoresponse at specific wavelengths.

### Nanopillar Optical Antenna Design

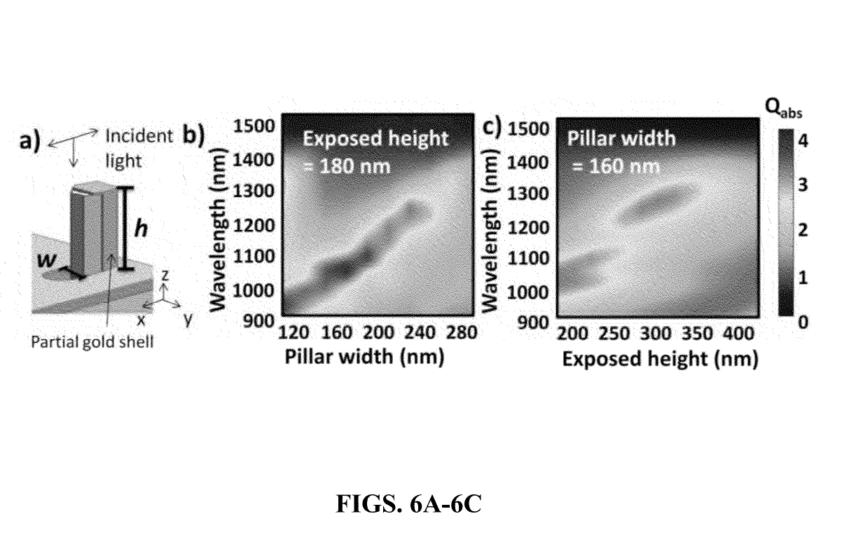

The NOA can be advantageous for improving the signal to noise ratio of nanopillar photodetectors because it allows optical absorption greater than geometrical cross-section of the nanopillar. FIG. 6A shows a schematic illustration of a single NOA which has a nanopillar with width w, exposed nanopillar height of h, and a partial gold shell. Specifically, h is the height of the nanopillar above the polymer (bisbenzocyclobutene—BCB) planarization layer. LSPRs can be spectrally tuned by varying the geometry of the (NOA) in terms of w and h. The NOA supports LSPRs due to the metal cap on top of the nanopillar, and the metal shell on the sidewalls of the nanopillar. The absorption of a single NOA is studied by full wave FDTD simulations using the total field scattered field approach. In the TFSF approach, the boundary conditions are Perfectly Matched Layer (PML) boundary conditions in the x- y- and z-boundaries, and the illumination is replaced with a total field/scattered field source, which isolates the scattered light outside the source [12, 13]. The optical properties of gold in the near infrared was modeled using Johnson and Christy [11]. Light is normally incident and polarized along the long edge (x-direction) of the nano-hole, such that it is more efficiently absorbed as reported previously [11]. The total electric field intensity enhancement inside the nanopillar is quantified using the normalized absorption cross-section (Q_{abs}) which is defined as the absorption cross-section normalized to the cross-section of the nanopillar as shown in Eq. (3). The parameters of Eq. (3) are ω which is the angular optical frequency, ∈″ is the imaginary part of the dielectric permittivity of In_{0.3}Ga_{0.7}As[14], |\vec{E}|² is the electric field intensity inside the nanopillar, I_{source} the intensity of the total field scattered field source, and A_{NP} the cross-section area of the hexagonal nanopillar [12]. Q_{abs} is a measure of the funneling of light from a larger collection area and absorption into the nanopillar.

$${Q}_{abs} = {\int \int \int }_{NP} \frac{\frac{1}{2} ω {ɛ}^{″} {\vert {E}^{->} \vert}^{2} d V}{{I}_{source} {A}_{NP}} \qquad ( 3 )$$

FIGS. 6B and 6C show contour plots of Q_{abs} as the geometry of the NOA is varied. In FIG. 6B h is kept constant at 180 nm, and the width of the nanopillar is varied. The peak value of Q_{abs} smoothly shifts to longer wavelengths with increasing width such that a maximum value of ˜3.9 is obtained for a width of ˜160 nm. In FIG. 6C w is kept constant at 160 nm, and the exposed height (h) is varied. The peak value of Q_{abs} in this case also shifts to longer wavelength as the exposed height increases, however there are two hot spots in the absorption cross-section. The first hot spot in the h=200-250 nm range is due to an LSPR supported mainly by the metal cap. The second hot spot in the h=300-350 nm is due to an LSPR supported mainly the partial metal shell. These simulations show that the NOA supports LSPRs, and that the optical absorption can be tuned by the three dimensional geometry of both the nanopillar gold cap and partial gold shell covering the nanopillar. The highest enhancement in Q_{abs} is obtained when h is equal to the thickness of gold on polymer planarization such that w=160 nm and h=180 nm.

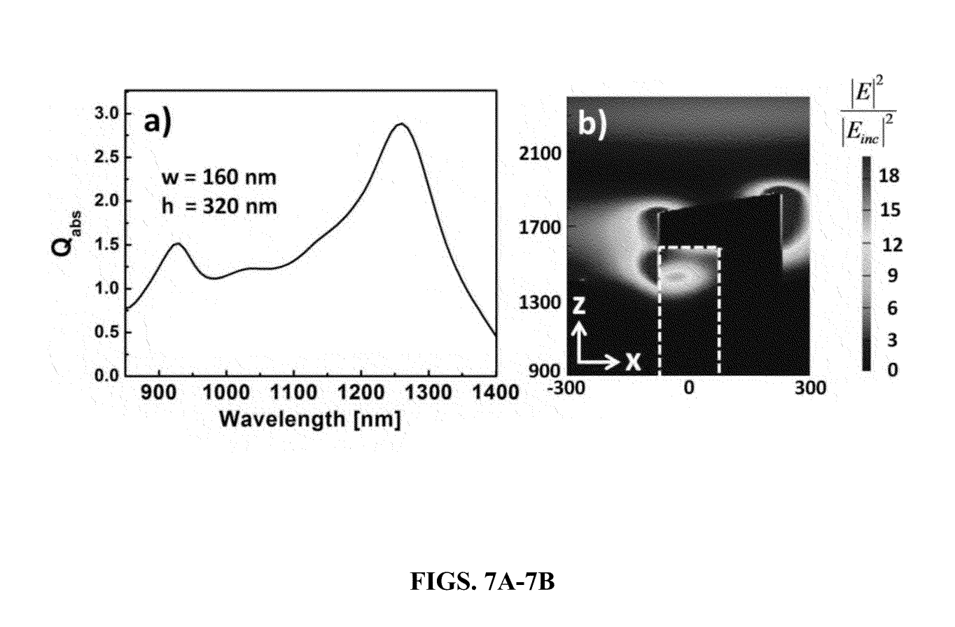

A representative spectrum of the enhancement of Q_{abs} is shown in FIG. 7A. The NOA geometry is such that w=160 nm and h=320 nm. The peak value of Q_{abs} is ˜2.8, while the peak absorption takes place at 1270 nm. This geometry of the NOA was chosen such that the LSPR could be clearly distinguished from the SPP-BW modes. FIG. 7B shows the electric field intensity in the x-z plane. The nanopillar is outlined by a dotted white line. Electric field enhancements within the nanopillar can result in useful photogeneration and enhanced photocurrent. The electric field extends from the metal cap on top of the nanopillar down to the nanopillar where it is absorbed. The LSPR due to the metal cap can be tuned by varying the exposed height of the nanopillar. At its peak value, the electric field intensity inside the nanopillar is x10 the incident electric field intensity. The LSPR forms a vertical dipole resonance from the metal cap on top of the nanopillar and the partial metal shell on the nanopillar sidewalls. This kind of LSPR is qualitatively similar to nanopatch antenna structure used for plasmonic lasers except the case of the NOA has a broken ground plane [15].

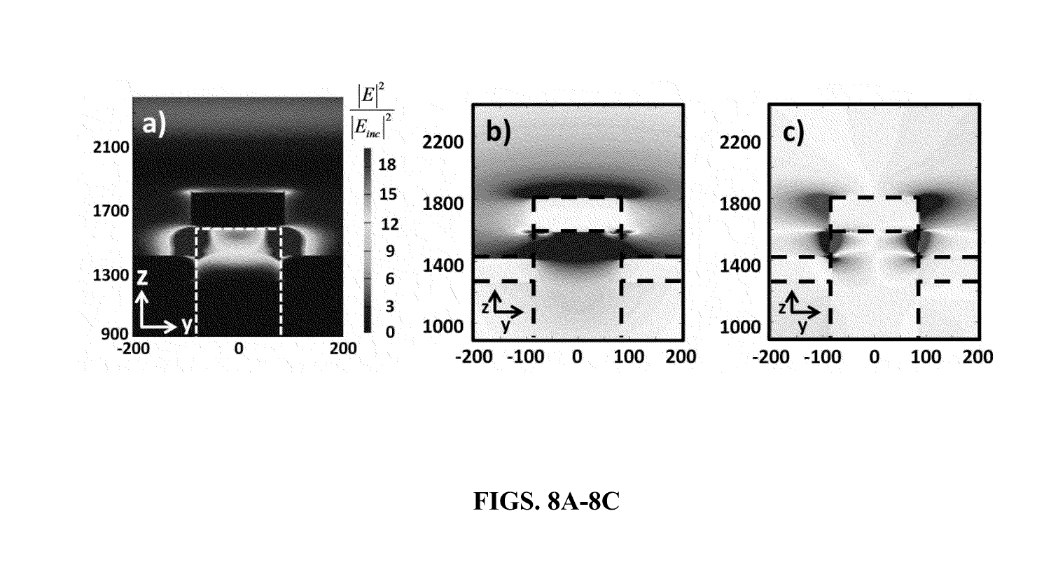

The nature of the LSPR due to the partial gold shell can be further investigated by decomposing the electric field intensity into its constituent field components. FIG. 8A shows the electric field intensity of the NOA structure in the y-z plane. The electric field intensity enhancement is greatest near the partial gold shell on the nanopillar sidewalls (greater than x18 the incident electric field intensity), and lowers towards the center of the nanopillar. FIG. 8B shows the electric field component in the z-direction (E_{z}). E_{z} is pointing downwards in the nanopillar and maximum in the center of the nanopillar. FIG. 8C shows the electric field component in the y-direction. The direction of E_{y} changes on the side walls of the nanopillar due to the partial metal shell coating the sidewalls. These results indicate that the enhancement in electric field intensity of the NOA is due to LSPRs of the metal cap on the nanopillar producing enhancement in the z-directed electric field and the partial metal shell on the sidewalls of the nanopillar producing an enhancement in the y-directed electric field.

NOAs can be arranged in a lattice such that the optical absorption can be further enhanced by the overlap of SPP-BWs [11] and LSPRs resulting in hybridized plasmonic modes for enhanced photoresponse. The boundary conditions of the simulation are changed to periodic boundaries in the x- y-directions, while the incident illumination is a plane wave source. The nanopillar exposed height and nanopillar width are chosen to be h=320 nm and w=160 nm to couple LSPRs due to the NOA structure described earlier. A pitch of 580 nm was chosen such that 1) the resonance of the SPP-BW can be clearly distinguished from the NOA resonance and 2) resonances are within the absorption spectrum of the In_{0.35}Ga_{0.65}As material.

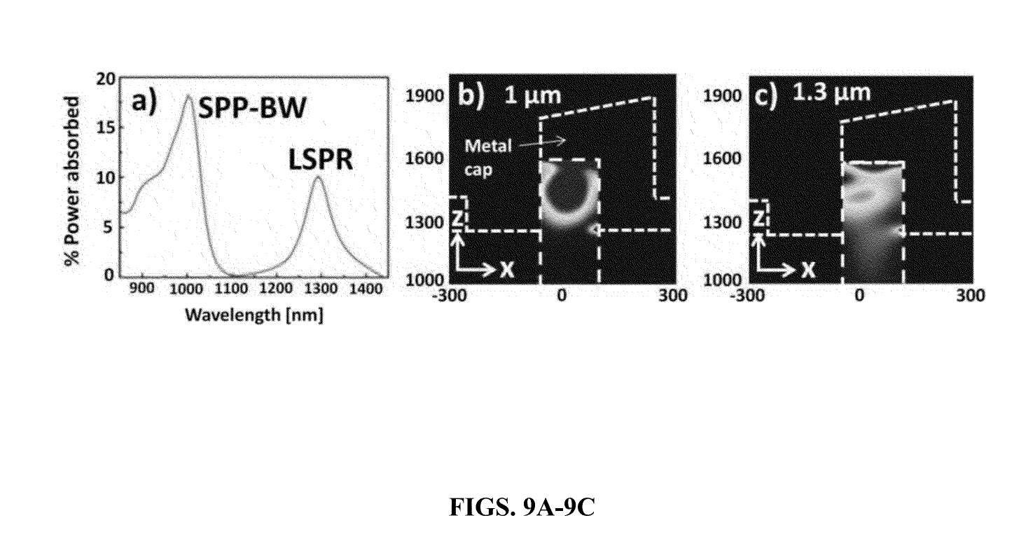

FIG. 9A shows the fractional power absorbed in the nanopillar per unit cell. The first peak at 1000 nm is due to the SPP-BW mode, which only appears when periodic boundary conditions are used. While the second peak at 1300 nm is due to the LSPR, which is the same as is present in FIG. 7A. Approximately 18% of the incident light is absorbed in the nanopillar due to the SPP-BW mode, while ˜10% is absorbed due to the LSPR mode at 1295 nm. It should be noted that the absorption efficiency of the SPP-BW mode is not limited to 18% and can be further enhanced by optimizing the geometry of the self-aligned nano-hole lattice. FIGS. 9B and 9C show the power absorption profile of the SPP-BW and the LSPR modes excited in the structure at normal incidence. In the case of the SPP-BW mode, light is focused away from the metal into the nanopillar, and extends downwards from the gold on top of the nanopillar. In contrast the second peak at 1300 nm has an absorption profile very similar to the LSPR described in FIG. 7B, which demonstrates that LSPRs supported by the NOA structure can be utilized for enhanced absorption in an array format.

### Device Fabrication and Characterization

Using the insight of FDTD simulations, NP-PEPDs are fabricated such that both LSPRs and SPP-BW modes can be observed in the photoresponse. The geometry of the 3D NOA and the self-aligned metal hole lattice is such that P=580 nm, w=160 nm, and h=320 nm. The nanopillars are composed of In_{0.3}Ga_{0.7}As p-doped at ˜10¹⁷ cm⁻³ a height of 1600 nm grown using selective area MOCVD on n+ GaAs substrate [11]. For the fabrication of the Nanopillar based Plasmonically Enhanced Photodetectors (NP-PEPDs) a gold top contact is evaporated on the nanopillar array at an angle of 40°, which produces a partial gold shell and the self-aligned metal hole. The top gold contact is electrically isolated via a BCB polymer planarization layer. The devices are diced and mounted on chip carriers for photoresponse characterization.

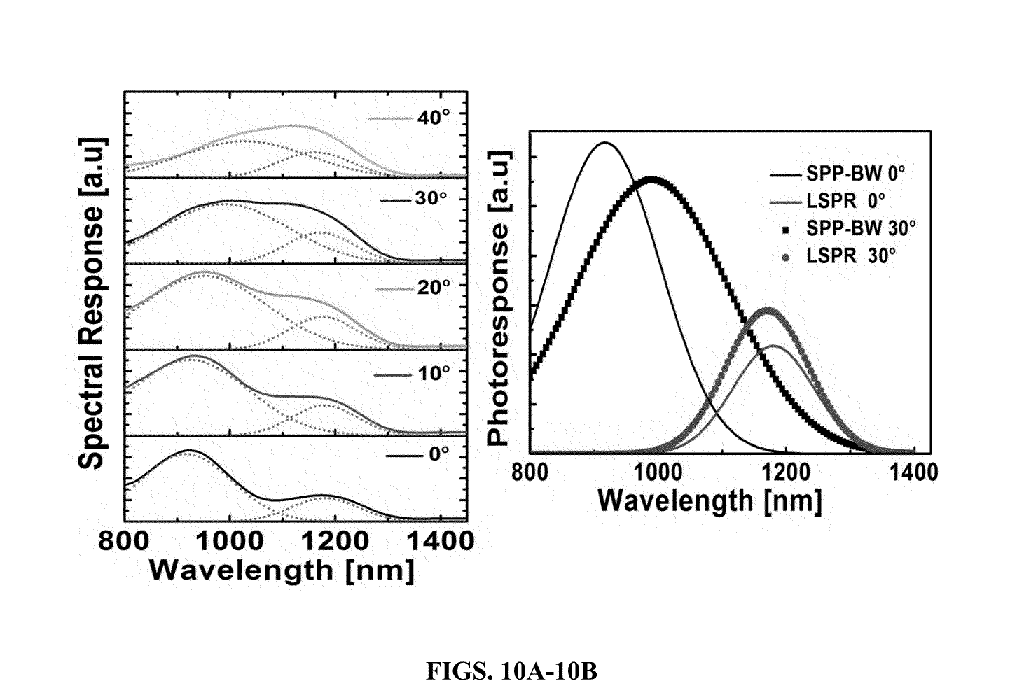

FIG. 10A shows the experimental angle-dependent photoresponse at zero bias of the NP-PEPD. For the photoresponse characterization the photocurrent of the wire bonded device is measured using a Keithley 2402 multimeter. Light from a quartz halogen lamp is dispersed by a grating monochromator and is incident on the device. Two peaks can be observed in the normal incidence photoresponse spectrum. The first peak at 923 nm is attributed to the SPP-BW_{(0,1)} mode corresponding to the FDTD mode calculated at 1000 nm while the second peak measured at 1200 nm is attributed to the LSPR calculated at 1275 nm. For the angular photoresponse characterization the sample is mounted on a rotation stage described previously[11] and tilted with respect to the incident light. When the device is tilted (θ) with respect to normal, incident photons have an in plane momentum given by kᵢₙ₋ₚₗₐₙₑ k₀ sin(θ) and the phase matching condition with surface plasmon polaritons is altered. FIG. 10A shows that the photoresponse due to the SPP-BW mode red shifts from 915 nm at θ=0° to 990 nm at θ=30° and spectrally overlaps with LSPR at 1180 nm for maximum enhanced photoresponse. The peaks of the photoresponse spectra are fitted to Gaussian peaks to determine the peak position and line width of the SPP-BW mode and LSPR. A Gaussian fitting was chosen because the device has ˜100,000 nanopillars such that the photocurrent measurement is an ensemble measurement. At θ=0° before the overlap of the SPP-BW and LSPR modes the responsivity at 1180 nm due to the LSPR is 0.048 A/W. Due to the overlap of the SPP-BW and LSPRs at θ=30° a responsivity of 0.096 A/W is measured at 1180 nm, which is a ˜x2 enhancement in the responsivity at LSPR wavelength due hybridization with the SPP-BW mode.

### Analysis and Discussion

To further understand the coupling of the hybrid plasmonic modes excited in NP-PEPD photonic bandstructure, calculations were performed. The photonic band structure of the device is computed by the fast fourier transform (FFT) of the time decay of the electric field intensity time monitor in the nanopillar. An excitation dipole placed above the elongated hole with Bloch boundary conditions, and the in-plane momentum is varied in the y-direction. These simulations performed with periodic boundary conditions reveal several modes which did not previously appear in the simulations performed with PML boundary conditions (FIG. 6, FIG. 7 and FIG. 8)—we consider these to be SPP-BW modes supported by the gold/bcb interface and the gold/air interface. However, only the SPP-BW mode due to the gold/BCB interface results in useful optical absorption in the nanopillar.

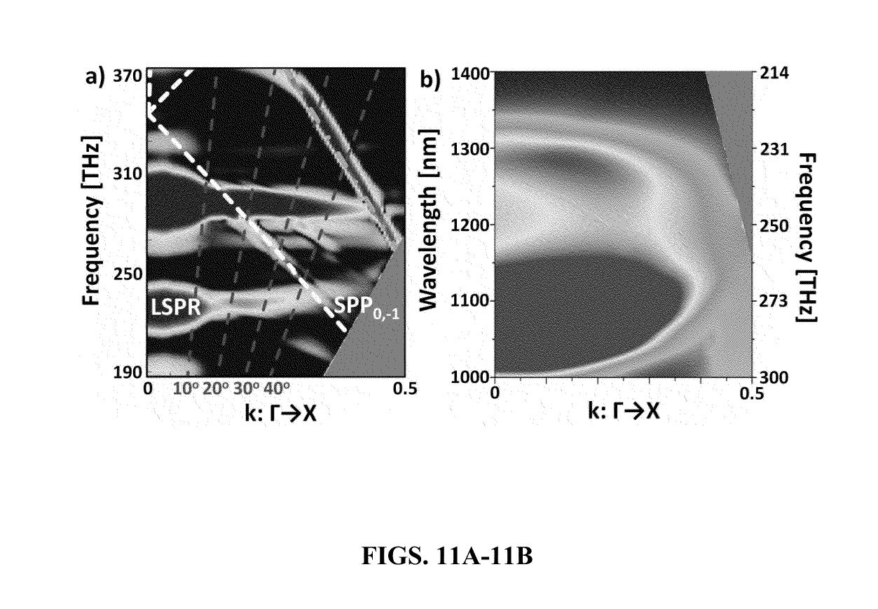

FIG. 11A shows the FDTD simulated bandstructure of the device with P=580 nm, w=160 nm, and h=320 nm. At the gamma point light couples predominantly into a band with a very low group velocity at 1000 nm (˜310 THz) such that the light is efficiently absorbed in the nanopillar, which is ideal for vertically incident photodetectors [16]. There is also a secondary peak at ˜1300 nm (˜230 THz) due to the LSPR, which shows little dispersion with in plane momentum characteristic of a localized resonance. FIG. 11A also shows the analytical SPP-BW dispersion of a gold hole array on polymer overlaid with the FDTD simulated bandstructure. The analytical expression for the dispersion of the SPP-BW modes is given by Eq. (4), [17, 18] where λ_{SPP-BW}_{_{i,j}} is the resonant scattering orders of the metal hole array, P is the pitch, ∈_{d} is the dielectric constant of the polymer, ∈_{Au} is the dielectric constant of the gold, and kᵢₙₚₗₐₙₑ is the in-plane momentum in the direction perpendicular to long side of the hole. There are three white lines which denote the Gold/polymer SPP-BW modes.

$${λ}_{SPP - {BW}_{i , j}} = \frac{2 π ( \frac{{ɛ}_{d} {ɛ}_{Au}}{{ɛ}_{d} + {ɛ}_{Au}} )}{{( {( \frac{2 π}{P} i )}^{2} + {( {k}_{inplane} \pm \frac{2 π}{P} j )}^{2} )}^{\frac{1}{2}}} \qquad ( 4 )$$

The SP_{(1,0)} and SPP_{(-1,0)} modes at 344 THz are degenerate at the gamma point and does not exhibit in-plane dispersion as these modes propagate in the x-direction. The SPP_{(0,1)} mode is also at 344 THz at the gamma point and shifts to shorter wavelengths with increasing in plane momentum. However, the SPP_{(0,-1)} mode shifts towards longer wavelength with increasing in plane momentum, and is the candidate SPP-BW mode for overlapping with the NOA resonance for enhanced photoresponse. Away from the gamma point the dispersion of the analytically computed SPP_{(0,-1)} matches that of the numerically computed bandstructure as is seen in the dotted white line in FIG. 11A. However this prediction fails close to the Gamma point (θ<10 degrees).

The dashed red lines in FIG. 11A correspond to the incident illumination being tilted an angle θ with respect to normal. From 0° to 20° the dispersion of the FDTD computed electric field intensity at 301 THz does not considerably red-shift with in-plane momentum, and is possibly do to SPP-BW mode having a very low group velocity. However, beyond 20° the SPP-BW red-shifts further such that at 30° the SPP-BW has the greatest overlap with LSPR. The dispersion of the numerically computed bandstructure matches the analytical expression for the SPP-BW_{(0,-1)} mode. Further increasing the incident angle results in the electric field intensity due to the SPP_{(0,-1)} being much weaker in the nanopillar resulting in reduced photoresponse. The bandstructure calculations qualitatively corresponds to the angular photoresponse measurements shown in FIG. 10. Due to the low group velocity of the SPP-BW mode the photoresponse peak does not shift with in plane momentum up to a tilt of 20°, beyond 20° the SPP-BW red shifts. In addition to the Gold/BCB SPP-BW modes the NP-PEPD structure also supports SPP-BW modes due to the Gold/Air interface shown as the dotted gray line, which has a good fit with the numerically computed FDTD bandstructure. However, these modes don't contribute to electric field intensity enhancement in the nanopillar resulting in useful photogeneration.

FIG. 11B shows the power absorbed in the nanopillar resulting in useful photoresponse. The SPP-BW mode from the gold/air interface (gray line in FIG. 11A doesn't contribute to useful photogeneration. However, the coupling of the SPP-BW (0,−1) from air/BCB interface and the LSP resonance results in enhanced photoresponse. The calculated power absorbed spectra in FIG. 11B supports the experimental result that a combination of SPP-BW_{(0,-1)} and the LSP resonance is producing enhanced photoresponse. Hybridizing SPP-BW modes with LSPRs results in photoresponse spectra that is more broadband than the individual plasmon resonances.

### CONCLUSIONS

In conclusion, we have demonstrated through detailed FDTD simulations and photoresponse measurements the presence of both SPP-BW modes and LSPRs in nanopillar photodetector arrays according to an embodiment of the current invention. Angular photoresponse measurements show how the hybridization of these resonances can be designed to be spectrally coincident for enhanced photoresponse. The nature of the LSP resonance is also investigated and is found to be tunable from the geometry of the NOA. Some embodiments of the current invention can provide small footprint photodetectors using NOA structure at the desired optical wavelengths. Structures like bullseye antennas, which can more efficiently hybridize SPP-BWs supported by the circular metal grating together with the LSPRs of the NOA structure, can also be used according to some embodiments of the current invention. These devices may have higher signal-to-noise ratio compared to a device composed of an array of NOAs. The ability to engineer the spectral overlap of both LSPRs and SPP-BWs allows the full utilization of the 3D geometry of the nanopillar for tunable and enhanced optical absorption.

### EXAMPLE 2 REFERENCES

1. L. Cao, J.-S. Park, P. Fan, B. Clemens, and M. L. Brongersma, “Resonant Germanium Nanoantenna Photodetectors,” Nano Lett. 10, 1229-1233 (2010).
2. L. Cao, J. S. White, J.-S. Park, J. A. Schuller, B. M. Clemens, and M. L. Brongersma, “Engineering light absorption in semiconductor nanowire devices,” Nat Mater 8, 643-647 (2009).
3. G. Bulgarini, M. E. Reimer, M. Hocevar, E. P. A. M. Bakkers, L. P. Kouwenhoven, and V. Zwiller, “Avalanche amplification of a single exciton in a semiconductor nanowire,” Nat Photon 6, 455-488 (2012).
4. P. Fan, U. K. Chettiar, L. Cao, F. Afshinmanesh, N. Engheta, and M. L. Brongersma, “An invisible metal-semiconductor photodetector,” Nat Photon 6, 380-385 (2012).
5. L. Tang, S. E. Kocabas, S. Latif, A. K. Okyay, D. S. Ly-Gagnon, K. C. Saraswat, and D. A. B. Miller, “Nanometre-scale germanium photodetector enhanced by a near-infrared dipole antenna,” Nat. Photonics 2, 226-229 (2008).
6. S. C. Lee, S. Krishna, and S. R. J. Brueck, “Quantum dot infrared photodetector enhanced by surface plasma wave excitation,” Opt. Express 17, 23160-23168 (2009).
7. T. Ishi, J. Fujikata, K. Makita, T. Baba, and K. Ohashi, “Si nano-photodiode with a surface plasmon antenna,” Jpn. J. Appl. Phys. Part 2—Lett. Express Lett. 44, L364-L366 (2005).
8. F.-F. Ren, K.-W. Ang, J. Ye, M. Yu, G.-Q. Lo, and D.-L. Kwong, “Split Bulls Eye Shaped Aluminum Antenna for Plasmon-Enhanced Nanometer Scale Germanium Photodetector,” Nano Lett. 11, 1289-1293 (2011).
9. P. Bouchon, F. Pardo, B. Portier, L. Ferlazzo, P. Ghenuche, G. Dagher, C. Dupuis, N. Bardou, R. Haidar, and J.-L. Pelouard, “Total funneling of light in high aspect ratio plasmonic nanoresonators,” Appl. Phys. Lett. 98, 191109-191103 (2011).
10. A. Akbari, R. N. Tait, and P. Berini, “Surface plasmon waveguide Schottky detector,” Opt. Express 18, 8505-8514 (2010).
11. P. Senanayake, C.-H. Hung, J. Shapiro, A. Lin, B. Liang, B. S. Williams, and D. L. Huffaker, “Surface Plasmon-Enhanced Nanopillar Photodetectors,” Nano Lett. 11, 5279-5283 (2011).
12. K. R. Catchpole and A. Polman, “Design principles for particle plasmon enhanced solar cells,” Appl. Phys. Lett. 93, 191113-191113 (2008).
13. S. Mokkapati, F. J. Beck, R. d. Waele, A. Polman, and K. R. Catchpole, “Resonant nano-antennas for light trapping in plasmonic solar cells,” Journal of Physics D: Applied Physics 44, 185101 (2011).
14. T. J. Kim, T. H. Ghong, Y. D. Kim, S. J. Kim, D. E. Aspnes, T. Mori, T. Yao, and B. H. Koo, “Dielectric functions of InxGal-xAs alloys,” Physical Review B 68, 10 (2003).
15. K. Yu, A. Lakhani, and M. C. Wu, “Subwavelength metal-optic semiconductor nanopatch lasers,” Opt. Express 18, 8790-8799 (2010).
16. J. Rosenberg, R. V. Shenoi, S. Krishna, and O. Painter, “Design of plasmonic photonic crystal resonant cavities for polarization sensitive infrared photodetectors,” Opt. Express 18, 3672-3686 (2010).
17. H. F. Ghaemi, T. Thio, D. E. Grupp, T. W. Ebbesen, and H. J. Lezec, “Surface plasmons enhance optical transmission through subwavelength holes,” Physical Review B 58, 6779-6782 (1998).
18. H. Gao, W. Zhou, and T. W. Odom, “Plasmonic Crystals: A Platform to Catalog Resonances from Ultraviolet to Near-Infrared Wavelengths in a Plasmonic Library,” Advanced Functional Materials 20, 529-539 (2009).

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. A plasmonically enhanced electro-optic device, comprising:
a dielectric layer;
a plurality of nanopillars arranged in a periodic array such that each nanopillar has a protruding portion that extends beyond a surface of said dielectric layer;
a metallic layer formed on said surface of said dielectric layer and on portions of said plurality of nanopillars by an oblique directional deposition such that said metallic layer defines a periodic array of nano-holes and nano-antennas, each nano-hole of said periodic array of nano-holes being in a deposition shadow region of a corresponding nanopillar; and
an electrode electrically connected to at least one nanopillar of said plurality of nanopillars at an end opposing said protruding portion thereof,
wherein each nanopillar of said plurality of nanopillars comprises a photo-absorption material, and
wherein said periodic array of nano-holes and nano-antennas have at least one of dimensions, uniformity or periodicity selected to enhance coupling of incident light into said plurality of nanopillars through excitation of surface plasmons.

2. A plasmonically enhanced electro-optic device according to claim 1, wherein said periodic array of nano-holes has substantially uniform hole sizes and shapes arranged with a periodicity to provide enhanced coupling through Surface Plasmon Polariton Block Waves.

3. A plasmonically enhanced electro-optic device according to claim 1, wherein said nano-antennas have a height above said surface of said dielectric layer and a width selected to provide enhanced coupling through Localized Surface Plasmon Resonances.

4. A plasmonically enhanced electro-optic device according to claim 2, wherein said nano-antennas have a height above said surface of said dielectric layer an a width selected to provide enhanced coupling through Localized Surface Plasmon Resonances.

5. A plasmonically enhanced electro-optic device according to claim 1, wherein said nano-antennas have a height of at least 150 nm and less than 800 nm above said surface of said dielectric layer.

6. A plasmonically enhanced electro-optic device according to claim 1, wherein said nano-antennas have a width of at least a detection wavelength divided by three times a refractive index of a material of said nanopillars and less than said detection wavelength.

7. A plasmonically enhanced electro-optic device according to claim 5, wherein said nano-antennas have a width of at least a detection wavelength divided by three times a refractive index of a material of said nanopillars and less than said detection wavelength.

8. A plasmonically enhanced electro-optic device according to claim 1, wherein said metallic layer comprises at least one of gold, silver, chromium, ITO, copper or a drude material.

9. A method of producing an electro-optic device, comprising:
providing a semiconductor substrate;
forming a mask layer on said semiconductor substrate, said mask layer defining a plurality of nano-holes therethrough to expose a pattern of regions of said semiconductor substrate;
growing a plurality of nanopillars from said plurality of nano-holes to provide a periodic array of nanopillars;
depositing a dielectric layer over said semiconductor substrate such that each nanopillar of said plurality of nanopillars has a protruding portion that extends beyond a surface of said dielectric layer; and
directionally depositing a metallic layer over said surface of said dielectric layer and portions of protruding portions of said plurality of nanopillars such that said metallic layer defines a periodic array of nano-holes in deposition shadow regions of said plurality of nanopillars and a plurality of nano-antennas on said plurality of nanopillars.

10. A method of producing an electro-optic device according to claim 9, further comprising selecting an angle of said directionally depositing relative to said surface of said dielectric layer such that nano-holes of said periodic array of nano-holes have preselected lengths extending from a respective nanopillar.

11. A method of producing an electro-optic device according to claim 9, further comprising selecting a dimension of said plurality of nano-holes through said mask layer such that said plurality of nano-holes of said metallic layer and said plurality of nano-antennas have a preselected width.

12. A method of producing an electro-optic device according to claim 10, further comprising selecting a dimension of said plurality of nano-holes through said mask layer such that said plurality of nano-holes of said metallic layer and said plurality of nano-antennas have a preselected width.

13. A method of producing an electro-optic device according to claim 9, wherein said growing said plurality of nanopillars grows said plurality of nanopillars to a preselected height, and
wherein said depositing said dielectric layer over said semiconductor substrate is deposited to a preselected thickness such that said plurality of nano-antennas have a preselected height and said array of nano-holes have preselected lengths extending from respective nanopillars.

14. A method of producing an electro-optic device according to claim 10, wherein said growing said plurality of nanopillars grows said plurality of nanopillars to a preselected height, and
wherein said depositing said dielectric layer over said semiconductor substrate is deposited to a preselected thickness such that said plurality of nano-antennas have a preselected height and said array of nano-holes have preselected lengths extending from respective nanopillars.

15. A method of producing an electro-optic device according to claim 12, wherein said growing said plurality of nanopillars grows said plurality of nanopillars to a preselected height, and
wherein said depositing said dielectric layer over said semiconductor substrate is deposited to a preselected thickness such that said plurality of nano-antennas have a preselected height and said array of nano-holes have preselected lengths extending from respective nanopillars.
